(19) United States
(12) Patent Application Publication
(10) Pub. No.: US 2010/0269894 A1
(43) Pub. Date: Oct. 28, 2010

(54) TITANIUM DIOXIDE NANOTUBES AND THEIR USE IN PHOTOVOLTAIC DEVICES

(75) Inventors: Manoranjan Misra, Reno, NV (US); Susanta Kumar Mohapatra, Lexington, KY (US); Subarna Banerjee, Reno, NV (US)

Correspondence Address: KLARQUIST SPARKMAN, LLP, 121 SW SALMON STREET, SUITE 1600, PORTLAND, OR, 97204, US

(73) Assignee: Board of Regents of the Nevada System of Higher Education, on Behalf of the University of Nevada, Reno (US)

(21) Appl. No.: 12/768,667

(22) Filed: Apr. 27, 2010

Related U.S. Application Data
(60) Provisional application No. 61/173,360, filed on Apr. 28, 2009.

(51) Int. Cl. H01L 31/02; C25D 1/00

(52) U.S. Cl. 136/252; 205/77; 977/840

(57) ABSTRACT

A titanium substrate is anodized to form an array of titanium dioxide nanotubes on the substrate surface. The nanotubes have hexagonal pore structures, are hexagonal in nature along their length and are tightly packed. The electrolyte solution used in the anodization process comprises the complexing agent Na₂[H₂EDTA]. The titanium dioxide nanotubes are formed at a rate of about 40 μm/hr. A titanium dioxide nanotube array detaches from the underlying titanium dioxide substrate by allowing the array to stand at room temperature, or by applying heat to the array. The resulting titanium dioxide membrane has a barrier layer on the back side of the membrane, which closes one end of the constituent nanotubes. The barrier layer can be removed via a chemical etch to create a membrane comprising nanotubes with open ends. The titanium dioxide membrane can be filled with a photosensitive dye and used as part of a dye sensitive photovoltaic devices.

### FIELD OF THE DISCLOSURE

The present disclosure relates to the formation and use of titanium dioxide nanotubes, and, more particularly, to the use of titanium dioxide nanotubes in photovoltaic devices.

### BACKGROUND

Dye-sensitive solar cells (DSSCs) are thin film photovoltaic devices that offer an attractive alternative to conventional solid-state semiconductor solar cells due in part to their physical integrity and their prospective low manufacturing costs. DSSCs hold promise as an inexpensive alternative to solid state semiconductor solar cells due to the relative low cost of starting materials and ease with which they can be manufactured. Generally, DSSCs include a transparent photosensitive electrode, a counter electrode and an electrolyte placed between the two electrodes. In one embodiment of conventional DSSCs, the photosensitive electrode includes glass covered with layers of fluorine-doped tin oxide (FTO), titanium dioxide and photosensitive dye.

Dye-sensitive solar cells produce current through the photoexcitation of electrons in the photosensitive dye, described as follows. Sunlight or light from any other source passing through the transparent electrode strikes the photosensitive dye. Photons impart energy to electrons of the dye molecules, causing them to excite into the conduction band of the dye, and drift to the TiO₂ material adjacent to the dye. These photoexcited electrons are replaced by electrons supplied by the electrolyte. In turn, the electrons contributed by the electrolyte are restored by the counter electrode.

To increase the rate of photoexcitation caused by photons hitting the photosensitive dye, the thickness of the photosensitive dye layer can be increased. One way of increasing the dye layer thickness is to provide a nanostructure on the photosensitive electrode capable of holding the dye. Titanium dioxide nanotubes have been used as nanostructures for holding photosensitive dye in DSSCs.

Titanium dioxide nanotubes can be formed through the anodization of titanium substrates. Generally, the formation of TiO₂ nanotubes on a titanium substrate through anodization is characterized by slow growth rates. TiO₂ nanotube membranes can be formed by separating TiO₂ nanotube arrays from the underlying titanium substrate. Conventionally, this separation is performed through mechanical and/or chemical processing involving hazardous materials such as ethanol, methanol bromine or HCl.

Thus, there is a need for DSSCs including titanium dioxide nanostructure membranes that can be grown quickly and separated from titanium substrates in a simple manner without the use of hazardous or toxic chemicals.

### SUMMARY OF THE DISCLOSURE

Disclosed herein are titanium dioxide nanotubes and methods of forming an array of such tubes. In one embodiment, the present disclosure provides methods of forming an array of titanium dioxide nanotubes by anodizing a titanium substrate. In some embodiments, the electrolyte solution used in the anodization process includes Na₂[H₂EDTA] as a complexing agent. In particular embodiments, the nanotubes are formed at a rate of between 0.5 μm/hr and 1,000 μm/hr, such as between 10 μm/hr and 100 μm/hr or between 20 μm/hr and 50 μm/hr; or about 20 μm/hr, about 30 μm/hr, about 35 μm/hr, about 40 μm/hr, or about 41 μm/hr. In some embodiments, the nanotubes have hexagonal pores. In other embodiments, the nanotubes are hexagonal along their length.

In another embodiment, the present disclosure provides methods for forming and using nanostructure membranes formed from titanium dioxide nanotube arrays. In some embodiments, a nanostructure membrane can be formed by separating a TiO₂ nanotube array from an underlying substrate by allowing the array to stand at room temperature or by applying heat to the array. In particular embodiments, a barrier layer on the back side of the membrane is removed.

In yet another embodiment, nanotube membranes comprise nanotubes that are opened at both ends, filled with a photosensitive dye and used as part of a photovoltaic device, such as a dye-sensitized solar cell.

The foregoing and other features and advantages of the disclosure will become more apparent from the following detailed description of several embodiments that proceed with reference to the accompanying figures. In this regard, it is to be understood that this is a brief summary of varying aspects of the subject matter described herein. The various features described in this section and below for various embodiments may be used in combination or separately. Any particular embodiment need not provide all features noted above, nor solve all problems or address all issues in the prior art noted above.

### BRIEF DESCRIPTION OF THE FIGURES

FIG. 1(a) shows perspective and side views of a titanium dioxide nanotube attached to a titanium substrate and having a barrier layer at one end.

FIG. 1(b) shows perspective and side views of a titanium dioxide nanotube separated from a titanium substrate, having a barrier layer at one end and partially filled with a liquid.

FIG. 1(c) shows perspective and side views of a titanium dioxide nanotube separated from a titanium substrate, having both ends open and filled with a liquid.

FIG. 2(a) is a schematic diagram illustrating a back side illuminated dye-sensitive solar cell comprising titanium dioxide nanotubes with a barrier layer.

FIG. 2(b) is a schematic diagram illustrating a front side illuminated dye-sensitive solar cell comprising titanium dioxide nanotubes with a barrier layer.

FIG. 2(c) is a schematic diagram illustrating a front side illuminated dye-sensitive solar cell comprising titanium dioxide nanotubes without a barrier layer.

FIG. 3 is a field emission scanning electron microscope image of TiO₂ nanotubes anodized at 80 V in an organic electrolyte (5 v % of water in ethylene glycol+0.5M NH₄F+0.25 M Na₂₁H₂EDTAD for one hour.

FIG. 4(a) is a field emission scanning electron microscope image of TiO₂ nanotubes showing the open ends of nanotubes formed by anodizing a titanium substrate for one hour.

FIG. 4(b) is a field emission scanning electron microscope image of TiO₂ nanotubes formed by anodizing a titanium substrate for one hour, viewed lengthwise.

FIG. 5 is a plot of anodization current density versus time for the anodization of a titanium substrate in fluoride+EDTA and fluoride only solutions.

FIG. 6 is scanning electron microscope images of Ti anodized at 100 V in ethylene glycol+water (5 v %)+0.25 M Na₂[H₂EDTA] at 80 V for one hour.

FIG. 7(a) is an optical image of a TiO₂ membrane having an area of 4 cm² and a thickness of 41.1 μm formed by anodizing a titanium substrate at 80 V for one hour in a solution of 5 v % of water in ethylene glycol+0.5M NH₄F+0.25 M Na₂[H₂EDTA]. The inset shows the TiO₂ membrane removed from the titanium substrate.

FIG. 7(b) is an optical image of a TiO₂ membrane having an area of 12.5 cm² and a thickness of 41.1 μm formed by anodizing a titanium substrate at 80 V for one hour in a solution of 5 v % of water in ethylene glycol+0.5M NH₄F+0.25 M Na₂[H₂EDTA].

FIG. 7(c) is an optical image of a TiO₂ membrane having area 12 cm² and a thickness of 20.0 μm formed by anodizing a titanium substrate for 30 minutes.

FIG. 8(a) is an optical image of a TiO₂ membrane having an area of 16.5 cm² formed by anodizing a titanium substrate in an EDTA+NH₄F+EG solution for one hour.

FIG. 8(b) is an optical image of TiO₂ membranes having various shapes.

FIG. 9(a) is a field emission scanning electron microscope image of the front side of titanium dioxide nanotubes.

FIG. 9(b) is a field emission scanning electron microscope image of the back side of titanium dioxide nanotubes.

FIG. 9(c) is a field emission scanning electron microscope image of the back side of a titanium dioxide nanotubes array.

FIG. 9(d) is a field emission scanning electron microscope image of the back side of a titanium dioxide nanotubes array showing opened pores after etching the back side of the array with aqueous HF.

FIG. 10 is a high resolution transmission electron microscopy image and a fast Fourier transformations pattern of a TiO₂ nanotube membrane.

FIG. 11(a) is a glancing angle X-ray diffraction plot of an as-anodized TiO₂ nanotube membrane.

FIG. 11(b) is a glancing angle X-ray diffraction plot of an O₂ annealed TiO₂ nanotube membrane.

FIG. 12 shows diffuse reflectance ultraviolet and visible spectra of TiO₂ nanotubes, dye-sensitized TiO₂ nanotube/titanium substrate structures and dye-sensitized TiO₂ membranes.

FIG. 13 shows diffuse reflectance ultraviolet and visible spectra of the open and closed ends of TiO₂ nanotubes.

FIG. 14 is an image of TiO₂ films produced by anodizing Ti foil in a solution of Na₂EDTA+NH₄F+EG for one hour. The TiO₂ film on the left side is arranged with the barrier layer facing upwards. The TiO₂ film on the right is arranged with the barrier layer facing down.

FIG. 15 is a plot of measured photocurrent versus potential for dye sensitized photovoltaic devices comprising: (a) a TiO₂ nanotube membrane unattached to a titanium substrate, having no barrier layer and treated with Ti(OPrⁱ) (front-side illuminated); (b) TiO₂ nanotubes attached to a titanium substrate treated with Ti(OPrⁱ) (front-side illuminated); and (c) TiO₂ nanotubes attached to a titanium substrate (back-side illuminated).

FIG. 16 is an SEM image of TiO₂ nanotubes comprising TiO₂ nanoparticles inside the TiO₂ nanotubes.

FIG. 17 is an SEM image of TiO₂ nanotubes comprising TiSi₂ nanoparticles inside the TiO₂ nanotubes.

FIG. 18(a) is an SEM image of a CdS quantum dot/TiO₂ nanotube hybrid material.

FIG. 18(b) is an SEM image of a PbS quantum dot/TiO₂ nanotube hybrid material.

FIGS. 19(a) and 19(b) are SEM images of Fe₂O₃ nanotubes.

### DETAILED DESCRIPTION OF SEVERAL EMBODIMENTS

As used in this application and in the claims, the singular forms “a,” “an,” and “the” include the plural forms unless the context clearly dictates otherwise. Similarly, the word “or” is intended to include “and” unless the context clearly indicates otherwise. The term “comprising” means “including;” hence, “comprising A or B” means including A or B, as well as A and B together.

The systems, apparatuses and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatuses are not limited to any specific aspect or feature or combinations thereof, nor do the disclosed systems, methods, and apparatuses require that any one or more specific advantages be present or problems be solved.

Although the operations of some of the disclosed methods are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures cannot show the various ways in which the disclosed systems, methods and apparatuses can be used in conjunction with other systems, methods and apparatuses.

Theories of operation, scientific principles or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following definitions are provided in order to aid in understanding the discussion of certain embodiments of the present disclosure that follow.

“Complexing agent” refers to compounds that can be used to increase the solubility of metals in a bath solution, or otherwise adjust the availability of metal ions for deposition. Common complexing agents include anions of metal salts, such as halides, sulfates, sulfites, thiosulfates, nitrates, nitrites, cyanides or thiocyanates. In some examples, the complexing agent is selected from oxycarboxylic acids, monocarboxylic acids, and polycarboxylic acids, and salts, other derivatives, and combinations thereof. Suitable examples of such acids include gluconic acid, glucoheptonic acid, oxalic acid, citric acid, tartaric acid, lactic acid, malic acid, malonic acid, acetic acid, succinic acid, gluconolactone acid, diglycolic acid, ascorbic acid, propionic acid, glucoheptlactone, formic acid, butyric acid, diglycolic acid, and salts, other derivatives, and combinations thereof. Suitable complexing agents further include disulfides, such as dithiodianiline and dithiodipyridine; thiocarboxylic acids, such as acetylcysteine and mercaptosuccinic acid; amino acids and thioamino acids, such as cysteine and methionine; thiourea and thiourea derivatives, such as trimethyl thiourea and allyl thiourea; sulfides, such as dimethyl sulfoxide (DMSO); and salts, other derivatives, and combinations thereof.

Complexing agents also refer to aldehyde compounds. Suitable examples include 2-thiophenaldehyde; 3-thiophenaldehyde; 1-naphthaldehyde; 2-naphthaldehyde; acetaldehyde; salicylaldehyde; o-anisaldehyde; m-anisaldehyde; p-anisaldehyde; salicylaldehyde allyl ether; o-chlorobenzaldehyde; m-chlorobenzaldehyde; p-chlorobenzaldehyde; 2,4-dichlorobenzaldehyde; and derivatives and combinations thereof.

In a specific embodiment, the complexing agent is a polyamine carboxylic acid, such as ethylenediamine; ethylenediaminetetraacetic acid (EDTA); hydroxyethylethylenediaminetriacetic acid (HEDTA); triethylenetetraminehexaacetic acid (TTHA); ethylenedioxybis(ethylamine)-N,N,N′N′-tetraacetic acid; diethylene-triaminepentaacetic acid (DTPA); ethylenetriamine; N-hydroxyethylenediamine (HEEDA); 1,2-diaminocyclohexane-N,N,N′,N′-tetraacetic acid; 1,3-diaminohydroxypropaney-N,N,N′,N′-tetraacetic acid; diethylenetriamine-N,N′,N′,N″,N″-petaacetic acid; and salts, other derivatives, and combinations thereof.

In further embodiments, the complexing agent is a substance selected from glycines; nitrilotrimethyl phosphonic acid; 1-hydroxyetane-1,1-diphosphonic acids; N,N-bis(2-hydroxyethyl)glycine; iminodiacetic acid; nitrilotriacetic acid; nitrilotripropionic acid; nitrilotriacetic acid (NTA); iminodiacetic acid (IDA); iminodipropionic acid (IDP); diethanolamine (DEA); triethanolamine (TEA); N-methylethanolamine; and 2-aminopropanol; and salts, other derivatives, and combinations thereof.

“Nanostructure” refers to a solid structure having a cross sectional diameter of between about 0.5 nm to about 500 nm Nanostructures may be made from a variety of materials, such compounds of titanium, silicon, zirconium, aluminum, cerium, yttrium, neodymium, iron, antimony, silver, lithium, strontium, barium, ruthenium, tungsten, nickel, tin, zinc, tantalum, molybdenum, chromium and mixtures thereof. Suitable compounds include transition metal chalcogenides or oxides, including mixed metal and/or mixed chalcogenide and/or mixed oxide compounds. In particular examples, the nanostructure is made from titanium dioxide.

In at least some examples, one or more materials from which the nanostructure is made are semiconductors. In some examples, the material has a band gap of at least about 2 eV, such as between about 2 eV and about 5 eV, between about 2 eV and about 4 eV, or between about 2 eV and about 3 eV, such as between about 2.0 eV and about 2.2 eV. In yet further examples, the material has a band gap of less than about 4 eV. In particular examples, the nanostructures have a resistivity lower than about 10⁻³ Ω·m, such as less than about 10⁻⁶Ω·m or less than about 10⁻⁷Ω·m, such as between about 10⁻¹⁴Ω·m and about 10⁻¹⁰Ω·m or between about 10⁻¹²Ω·m and about 10⁻⁶Ω·m. In some embodiments, the nanostructures have a resistivity of about 10⁻¹²Ω·m.

Nanostructures can be formed in a variety of shapes. In one implementation, the nanostructures are nanotubes. In some implementations, the cross sectional dimension of the nanostructure is relatively constant. However, the cross sectional dimension of the nanostructure can vary in other implementations, such as rods or tubes having a taper. In some embodiments, the cross-sectional shape of the nature can be substantially constant along the length of the nanostructure as well.

“Pulse electrolysis” refers to electrochemical methods where current is applied in a time varying manner, as opposed to constant, direct current techniques. Pulse electrolysis can be used in various material or device fabrication techniques, such as anodization or electrodeposition.

“Substrate” refers to a material onto which nanostructures are attached or are formed. Suitable substrates include generally inert materials, which are typically also insulating. The substrate is typically selected to be stable during the processes by which the nanostructures are placed or formed on the substrate. For example, in some methods, the substrate is capable of withstanding relatively high temperatures, such as at least about 500° C. Examples of substrate materials include ceramics, glasses, such as silica, fluorine-doped tin oxide (FTO) glass, or soda-lime glass, quartz, alumina, silica, and insulating polymers.

Prior to use, the substrate may be subjected to one or more pretreatment steps, such as cleaning steps. Cleaning steps can include treating the substrate with a solvent, such as an organic solvent, to remove impurities present on the surface of the substrate. In a particular example, the solvent is acetone. Ultrasonication may also be used to clean the surface of the substrate.

The dimensions of the substrate can be tailored to a particular application, such as the nanostructure composition, size, desired detection limit, and other components of an apparatus with which the nanostructure array will be used. In particular examples, the substrate has a thickness of between about 0.25 mm and about 2 mm, such as between about 0.5 mm and about 1 mm, including 0.5 mm, 0.6 mm, 0.7 mm, 0.8 mm, 0.9 mm or 1 mm.

Additional materials can be placed on the substrate, such as to facilitate handling of the structure or to aid in subsequent processing steps. For example, in some methods, a layer of aluminum is deposited on the substrate prior to deposition of the material from which the nanostructures will be formed.

Terms modified by the word “substantially” include arrangements, orientations, spacings or positions that vary slightly from the meaning of the unmodified term. For example, nanotubes having substantially hexagonal pores include nanotubes having pores with interior angles all within a few degrees of each other.

The presently disclosed embodiments are directed to nanostructure arrays, nanostructure membranes, methods for their synthesis, and methods of their use. Nanostructure membranes refer to a film or layer of nanostructure material that has been removed from a base layer or substrate from which it was formed. A nanostructure membrane can comprise a nanostructure array. In some examples, the nanostructure membranes have been treated such that the nanostructure material is permeable on both sides of the membrane. For example, a nanostructure membrane can comprise hollow nanostructures. That is, a nanostructure membrane can comprise nanostructures having opposite ends that are open.

It is to be understood that stated properties or features of nanotubes comprising nanotube arrays or membranes are possessed by all or almost all of the nanotubes of the array or membranes. That is, individual nanotubes of the membrane or array may not possess the stated feature or property. For example, when a nanotube membrane is stated to be comprised of nanotubes having back side ends that have been opened up due to the removal of a barrier layer via chemical etch, the membrane or array may still comprise nanotubes having closed ends.

Nanostructure membranes can be comprised of nanotubes, such as TiO₂ nanotubes. One suitable method of forming nanotubes involves anodizing a metal or metal alloy source, such as titanium foil, in a suitable electrolytic solution. Suitable titanium foils can be obtained from commercial sources or can be prepared by various methods, such as sputtering. The thickness and shape of the material to be anodized can vary, including the desired shape of nanostructured material and the desired nanostructure length or layer thickness.

Prior to anodization, the metal source can be cleaned, such as by washing the source in an organic solvent, such as acetone, methanol, isopropanol, or mixtures thereof (including aqueous mixtures), optionally with sonication. The metal source can be further rinsed with water, such as deionized water, and dried.

In some embodiments, the electrolytic solution or bath includes water, a fluoride compound, such as hydrogen fluoride, ammonium fluoride, or alkali fluorides, such as sodium fluoride or potassium fluoride. The solution includes at least about 0.1 wt % of fluoride compounds in some examples, such as about 0.5 wt % of one or more fluoride compounds. In other examples, the fluoride compound is present at a concentration of at least about 0.1 M, such as about 0.5 M. The solution further includes a complexing agent, such as EDTA, for example Na₂[H₂EDTA]. In specific examples, the complexing agent is present in a concentration of between 0.05 M and 1M, such as about 0.25 M. The electrolytic solution can also include a polar organic solvent, such as those having a dielectric constant of at least about 10 at 25 and a boiling point of at least about 100° C. Solvents that can be used include alkylene glycols such as ethylene glycol, and organic solvents such as dimethyl formamide and glycerol.

In some embodiments, the electrolytic solution includes at least one acid, such as acetic acid, chromic acid, phosphoric acid, oxalic acid, hydrofluoric acid, or mixtures thereof. In other implementations, a basic electrolytic solution is used, such as a solution of potassium hydroxide. The electrolyte solution can include other substances.

In various examples, the anodization potential is between about 1 V and about 200 V, such as between about 10 V and about 100 V or about 80 V. In a specific example, the anodization voltage is 80 V. Constant anodization voltages can be used to produce nanotubes having a relatively constant diameter. Ramped or stepped voltages can be used to produce shaped nanotubes, such as tapered conical nanotubes. Pulsed electrolysis can be used to perform the anodization.

The use of pulse electrolysis can result in a more uniform or homogenous surface as compared to other electrolysis techniques. When used for electrodeposition, pulse electrolysis can result in fine grain deposition. Compared with direct current techniques, pulse current techniques can allow a higher instantaneous current density to be delivered to the anode. These techniques can be applied in both acidic and basic bath solutions. Acidic solutions tend to be more efficient, but can result in more than one phase being formed. In some embodiments of the present disclosure, it can be advantageous to have a less homogenous coating, or one having more than one phase, as these qualities can produce more exchangeable sites which can then be sensitized using a desired agent, as described elsewhere in this disclosure.

In particular examples, pulse electrolysis is carried out at a temperature of between about 15° C. and about 120° C., such as between about 20° C. and about 80° C., for example, at 25° C. The cathodic current density is typically between about 0.1 A cm⁻² and about 20 A cm⁻², such between about 3 A cm⁻² and about 10 A cm⁻², or about 6 A cm⁻². Cathodic current on time is typically between about 0.05 ms and about 5 s, such as between about 0.1 ms and about 10 ms. Cathodic current off time is typically between about 0.05 ms and about 400 ms, such as between about 0.25 ms and about 9 ms. An anodic pulse is applied, in some examples, during all or part of the current off time, such as for a duration of between about 0.05 ms and 50 ms, such as between about 0.25 ms and about 15 ms. In further examples, the current off time is used as a rest period and no current via an anodic pulse is applied during this time.

In other embodiments, the cathodic current density is typically between about 0.005 A cm⁻² and about 200 A cm⁻², such as between about 1 A cm⁻² and about 100 A cm⁻² or between about 1 A cm⁻² and about 10 A cm⁻². Anodic current density is typically between about 0.05 A cm⁻² and about 1 A cm⁻², such as between about 0.1 A cm⁻² and about 0.5 A cm⁻². In at least some examples, finer grain deposits can be formed by increasing the electrolytic parameters, such as increasing the cathodic current density, the anodic current density, the cathodic on time, and the cathodic off time.

An increase in cathodic current density can result in a smaller grain size and a higher nucleation rate. An increase in cathodic on time can lower surface roughness, as it can decrease grain size and result in more spherical grains. Although increasing cathodic current off time can result in finer grain sizes, current times that are too long, such as greater than about 5 ms, can result in local corrosion, resulting in surface flaws. Increasing the peak anodic current density also results in finer grain size and grains that are more spherical. Increasing the anodic current density above about 0.2 A cm⁻² can result in surface defects, such as, for example, by ionization of surface components. The potential needed to reduce, or oxidize, a particular metal in the electroplating method can be determined by standard means, including determination of the overpotential for a particular cell needed to deposit or anodize a particular substance.

The temperature of the anodization process can also affect the properties of the nanostructures. In embodiments where the nanostructures are nanotubes, temperature can affect nanotube wall thickness. Lower anodization temperatures typically produce nanotubes having thicker walls. Typical temperatures are between about 5° C. and about 75° C., such as between about 15° C. and about 50° C. The pH of the electrolyte solution is typically between about 0.1 to about 7, such as between about 3 and about 5.

In at least some implementations, the bath is agitated during all or a portion of the anodization process. Suitable means of agitation include magnetic or mechanical stirring. Ultrasonication can also be used to agitate the electrolyte solution.

Anodization is carried out for a sufficient time to form nanostructures having a desired length or other property, such as between about 1 minute and about 24 hours. Amorphous nanostructures produced by such methods can be crystallized by annealing the nanostructures, such as by heating the nanostructures at a suitable temperature of about 200° C. to about 1200° C. and for a period of about 10 minutes to about 7 hours.

The nanostructure arrays and membranes described herein can be used for a variety of applications, including photocleavage of water and photocatalytic dye degradation. The nanostructure arrays and membranes can also be employed as sensors. In a particular application, the nanostructure arrays and membranes are used in photovoltaic devices such as dye-sensitized solar cells (DSSCs).

When prepared as described in the present disclosure, TiO₂ nanostructure membranes can be removed from a titanium substrate by allowing the TiO₂ membrane/Ti substrate structure stand at room temperature or by applying heat to the structure, such as with a heat gun. In doing so, the nanotube membranes separate from the underlying Ti substrate.

In other examples, TiO₂ nanotubes produced by anodization of a titanium substrate, which may be formed under conditions other than those disclosed herein, are removed from the Ti substrate by other methods, such as ultrasonication in ethanol-water, ultrasonication in ethanol, methanol treatment, hydrochloric acid treatment, and dissolution in water-free methanol/bromine solution. Suitable anodization methods and membrane separation techniques are disclosed in the following documents, each of which is incorporated by reference herein to the extent not inconsistent with the present disclosure: Park, et al., Chem. Commun 2008, 2867; Chen, et al., Nanotechnology 2008, 19, 365708; Albu, et al., Nano Lett. 2007, 7, 1286; Paulose, et al., J. Phys. Chem. C 2007, 111, 14992; Wang, et al., Chem. Mater. 2008, 20, 1257. However, these separation methods can require an extra fabrication step (e.g., chemical etch, ultrasonication) and involve the use of hazardous chemicals (i.e., ethanol, bromine, methanol). Separation of TiO₂ nanotubes from a titanium substrate by allowing the structure to stand at room temperature or by applying heat thus provides a safer and quicker separation method. In some examples of the present method, separation of TiO₂ nanotubes from a titanium substrate occurs in the absence hazardous chemicals such as in the absence of ethanol, bromine, methanol or a combination thereof.

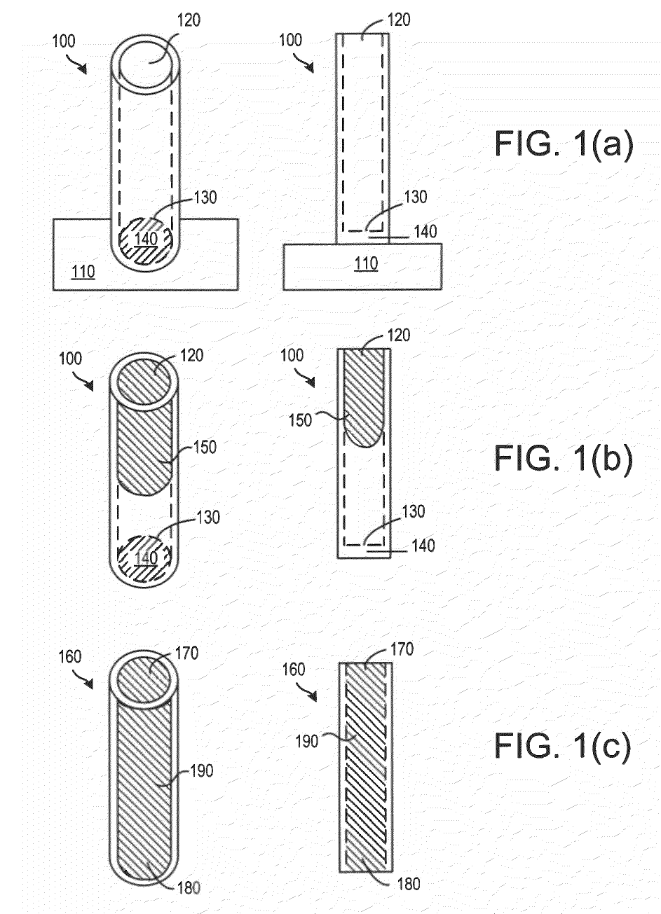

FIG. 1(a) shows perspective and side views of a titanium dioxide nanotube 100 attached to a metallic substrate 110, such as the titanium substrate from which the nanotube 100 was formed. The nanotube 100 includes an open end 120 and a closed end 130 due to the presence of a barrier layer 140. The barrier layer 140 can be formed during the anodization of the nanotube 100. In the case where a titanium substrate is anodized to form titanium dioxide nanotubes, the bather layer is made of titanium dioxide. FIG. 1(b) shows the TiO₂ nanotube 100 after being separated from the substrate 110. The barrier layer 140 remains attached to the nanotube 100, resulting in end 130 still being closed. The closed end 130 creates surface tension caused by the air trapped inside the nanotube, which results in a liquid 150, such as a photosensitive dye, being unable to occupy the entire interior volume of the nanotube 100. FIG. 1(c) shows a TiO₂ nanotube 160 with open ends 170 and 180, and having no barrier layer. The absence of a closed end allows a liquid 190 to occupy all or most of the interior volume of the nanotube 160.

In any of the embodiments described herein, the barrier layer can be removed from titanium dioxide nanotubes. Removing the barrier layer opens the nanotubes at each end, which can allow liquids to flow through the nanotube, or enter the nanotube to a greater extent than if the bather layer were not present. A nanotube having both ends open has improved wettability, dye absorption, photon transport, and electrolyte uptake. Barrier layer removal can be accomplished by contacting a nanotube membrane with a suitable etchant, such as HF.

The disclosed method of forming nanotube arrays can be beneficial compared with other methods, as it can more rapidly and with lower toxicity produce nanotube membranes, which can then be etched with a suitable etchant, such as HF, to remove the barrier layer and open both nanotube ends.

Photovoltaic devices such as solar cells can be formed by combining a nanostructure array of the present disclosure, more particularly a nanostructured membrane, and even more particularly a nanostructured membrane having nanotubes open at each end, with a transparent substrate to form a photosensitive electrode. The photosensitive electrode is typically combined with a counter electrode, such as a transparent counter electrode. In a specific example, the counter electrode is platinum on fluorine-doped tin oxide (FTO) glass. The solar cell also typically includes a photosensitive dye, such as cis-bis(isothiocyanato)bis(2,2′-bipyridyl-4,4′-dicarboxylato)-ruthenium(II)bistetrabutylammonium dye, and an electrolyte.

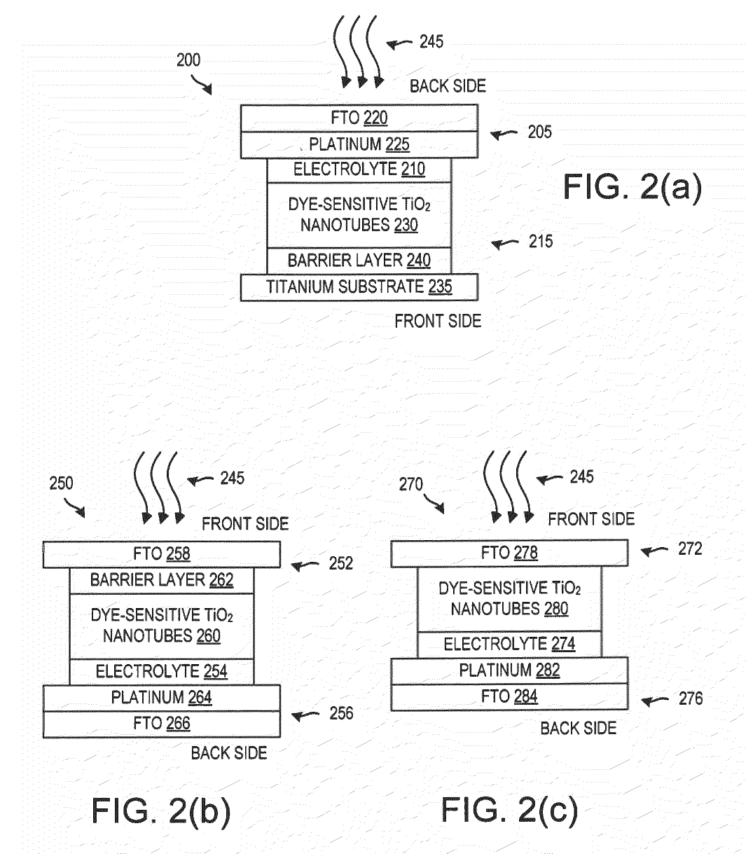

FIGS. 2(a)-2(c) illustrate various dye-sensitized solar cell configurations comprising titanium dioxide nanotubes. FIG. 2(a) illustrates a DSSC 200 comprising a counter electrode 205, an electrolyte 210, and a photosensitive electrode 215. The counter electrode 205 comprises FTO glass 220 coated with a layer of platinum 225. The photosensitive electrode 215 comprises dye-sensitive TiO₂ nanotubes 230 and a titanium substrate 235 and a barrier layer 240. Dye-sensitive TiO₂ nanotubes refer to TiO₂ nanotubes that are at least partially filled with photosensitive dye. DSSC 200 is shown as being illuminated on the back side as the incident light 245 passes through the counter electrode 205 before striking the photosensitive electrode 215, the back and front sides of a DSSC being defined relative to the location of the photosensitive electrode. Light striking a front-side illuminated DSSC can strike the photosensitive electrode before striking the counter electrode. The light 245 striking the DSSC 200 passes through the counter electrode 205 and the electrolyte 210 before reaching the photosensitive electrode 215. If I₀ is the intensity of the incident light, and I is the intensity of light falling on the dye-sensitized TiO₂ nanotubes, the loss of intensity is given by I₀-I.

FIG. 2(b) illustrates a front side illuminated DSSC 250 comprising a photosensitive electrode 252, an electrolyte 254 and a counter electrode 256. The photosensitive electrode 252 comprises an FTO glass layer 258, dye-sensitive TiO₂ nanotubes 260 and a barrier layer 262. The bather layer 262 is positioned between the FTO glass layer 258 and the TiO₂ nanotubes 260. The counter electrode 256 comprises a layer of platinum 264 and a layer of FTO glass 266. Although the incident light 245 does not pass through the counter electrode 256 and electrolyte 254 before reaching the dye-sensitive TiO₂ nanotubes 260, the light 245 passes through the bather layer 262 before reaching the nanotubes 260.

FIG. 2(c) illustrates a front-side illuminated DSSC 270 comprising a photosensitive electrode 272, an electrolyte 274 and a counter electrode 276. The photosensitive electrode 272 comprises an FTO glass layer 278 and dye-sensitive TiO₂ nanotubes 280. The counter electrode 276 comprises a layer of platinum 282 attached to a layer of FTO glass 284. The photosensitive electrode 272 does not comprise an attached barrier layer. Thus, a greater portion of the incident light 245 can reach the TiO₂ nanotubes 280 relative to the TiO₂ nanotubes 230 and 260 in DSSCs 200 and 250, respectively. Because DSSC 270 does not have a barrier layer, it is referred to as a flow through system. In embodiments where the TiO₂ nanotubes are attached to the FTO glass 284 by a porous layer of transparent TiO₂ nanoparticles formed by the segregation of Ti-isopropoxide, photosensitive die can flow through the TiO₂ nanotubes 280 even after the nanotubes 280 are attached to the FTO glass 284. Thus, adsorption of the photosensitive dye can occur along the most or all of the length of the TiO₂ nanotubes 280. Although not shown, any of the DSSCs illustrated in FIG. 2 or otherwise described herein can be illuminated on both the photosensitive electrode (front) side and counter electrode (back) sides simultaneously to increase the photoelectric current produced by the DSSC.

As front side-illuminated DSSC 270 has fewer layers (FTO layer 278) for the incident light 245 to pass through before reaching the dye-sensitive TiO₂ nanotube membrane 280 relative to front side illuminated DSSC 250 (FTO layer 258, barrier layer 262) and back side illuminated DSSC 200 (FTO layer 220, platinum layer 225, electrolyte 210), the DSSC 270 can produce a greater photocurrent relative to DSSCs 200 and 250.

### Example

The following example provides a method for forming titanium dioxide nanotube arrays and membranes, dye sensitized solar cells employing titanium dioxide nanotubes and their use. Advantages provided by the method of the example include at least single-step anodization and detachment of the TiO₂ nanotube array from the titanium substrate surface without the use of hazardous or toxic chemicals to perform the detachment, fast nanotube growth rates up to 41 μm/h, hexagonal-shaped nanotubes with 182 nm pore openings, highly transparent TiO₂ membranes, ability of the titanium substrate to be reused, and high DSSC photocurrent densities.

### Materials and Methods

In this example, titanium foil (Ti, 99.9%; ESPI-metals, Oregon, USA), ethylene glycol (Fischer, 99.5%), ammonium fluoride (NH₄F, Fischer, 99.5%), disodium ethylenediamine tetraacetate (Na₂[H₂EDTA]) (Fisher Scientific, 99.6%), cis-bis(isothiocyanato)bis(2,2′-bipyridyl-4,4′-dicarboxylato)-ruthenium(II)bistetrabutylammonium (N719) Dye (Solaronix), 1,3-dimethyl imidazolium iodide (Fluka, 98%), iodine (Sigma-Aldrich, 99.99% metal basis), 1-methyl benzimidazole (Aldrich, 99%), guanidine thiocyanate (Sigma-Aldrich, 99%), 3-methoxy propionitrile (Fluka, 98%), acetonitrile (Sigma-Aldrich, 99% ACS grade), tert-butanol (Sigma-Aldrich, 99% ACS grade) were used as-received.

### Preparation of TiO₂ Templates

Titanium foils were cut into the desired size and shape, cleaned in acetone, dried and then processed for anodization. The anodization was carried out using ultrasonic waves (100 W, 42 kHz, Branson 2510R-MT) by immersing a part of the Ti foil (total geometrical area 4 cm² and 12.5 cm²) in the electrolytic solution (1000 ml). Water (5 v %), 0.5 M NH₄F, 0.25 M Na₂[H₂EDTA] and ethylene glycol were mixed together thoroughly and used as the electrolytic solution (pH=6.4-6.5). Titanium foil served as the anode and platinum (Pt) as the cathode. The anodization was carried out for one hour at an applied potential of 80 V using a rectifier (Xantrex, XFR 600-2). A sonoelectrochemical anodization method was used rather than a conventional magnetic stirring method, as sonoelectrochemical methods can provide higher quality nanotubes with cleaner surfaces. The anodization current was monitored continuously using a digital multimeter (METEX, MXD 4660A). The anodized samples were washed with distilled water to remove the occluded ions, dried in an air oven, and processed for further experiments and studies. The TiO₂ nanotubes were annealed under oxygen (O₂) atmosphere in a chemical vapor deposition furnace (CVD, FirstNano) at 500° C. for 6 h to yield crystalline TiO₂ nanotubes.

Preparation (Detachment from Ti Substrate) and Characterization of TiO₂ Membrane.

The as-anodized TiO₂ nanotubes were detached from the metallic Ti substrate, the titanium foil, by keeping the templates at room temperature whereby the array detaches from the substrate on its own. The separation process can be sped up by heating the nanotube/substrate structure, such as by using a hot air gun. The detached TiO₂ nanotube membrane was etched with a solution of 5% aqueous hydrofluoric acid (HF) from the back side whereby the bather layer was dissolved. A TiO₂ nanotube membrane was obtained by this process comprising nanotubes with both ends open. This membrane was layered on FTO coated glass (Hartford Glass Co., Inc.) and sealed to the glass by drops of titanium isopropoxide (Ti(OPrⁱ)). The Ti(OPrⁱ)-treated membrane was annealed under O₂ atmosphere in a CVD (chemical vapor deposition) furnace at 500° C. for 6 h to convert the amorphous TiO₂ nanotubes into crystalline TiO₂ nanotubes.

A field emission scanning electron microscope (FESEM; Hitachi, S-4700) was used to analyze the morphology of the nanotubes both before and after functionalization (i.e., annealing the amorphous nanotubes to make them crystalline). TEM (transmission electron microscopy) measurements were carried out by ultrasonicating a part of the membrane in ethanol for a few minutes. A drop of ethanol containing a nanotube sample was placed on a carbon coated Cu-grid and subjected to high resolution transmission electron microscopy (HRTEM) and fast Fourier transformations (FFT) measurements. Glancing angle X-ray diffraction (GXRD) was performed using a Philips-12045 B/3 diffractometer. The target used in the diffractometer was copper (λ=1.54 Å), and the scan rate was 1.2 deg./min

### Dye Sensitization of TiO₂ Nanotubes and Characterization of Dye-Sensitized TiO₂ Nanotubes

All fabrication steps of the DSSCs were performed in air. To fabricate the DSSCs, both the annealed TiO₂ nanotube array/Ti substrate structure and the Ti(OPrⁱ)-treated TiO₂ nanotube membrane layered onto FTO glass were sensitized by soaking the structures for 16 h in a 5×10⁻⁴ M solution of the N719 dye in acetonitrile/tert-butanol (1:1 v/v) binary solvent. This was followed by rinsing the samples with acetonitrile in order to remove any physisorbed dye. Diffuse reflectance ultraviolet and visible (DRUV-Vis) spectra of the samples were measured from the optical absorption spectra using a UV-Vis spectrophotometer (UV-2401 PC, Shimadzu) to understand the solar light harvesting properties of the material. Fine BaSO₄ powder was used as a standard for baseline measurements and the spectra were recorded in a range of 200-800 nm.

### Photovoltaic Measurements

For photovoltaic measurements, the dye-sensitized TiO₂ nanotube array/Ti substrate structures were incorporated as the active photoelectrode in a solar cell configuration and characterized using back side illumination conditions. TiO₂ nanotube arrays/Ti substrate structures and Ti(OPrⁱ)-treated TiO₂ membrane layered onto FTO glass structures were incorporated as the solar cell active photoelectrode and characterized by front side illumination. Platinum coated FTO glass was used as a counter electrode in all the measurements. The FTO glass pieces were cut into the desired size and dipped in a solution of chloroplatinic acid (H₂PtCl₆) and annealed in hydrogen at 450° C. for 1 h in a CVD furnace to produce Pt coated FTO glass. Non-sealed DSSCs were fabricated by putting a small drop of ionic-salt-based liquid electrolyte (1.0 M 1,3-dimethylimidazolium iodide, 0.15 M I₂, 0.5 M 1-methylbenzimidazole, and 0.1 M guanidinium thiocyanate in 3-methoxypropionitrile) onto the photoelectrode and sandwiching the counter electrode on top of the first electrode. An adhesive tape mask was placed between the two conductive surfaces in order to avoid short-circuiting.

Current-voltage (I-V) measurements were performed by illuminating the DSSCs through the transparent counter electrode for the samples comprising TiO₂ nanotube array/Ti substrate structures and Ti(OPrⁱ)-treated TiO₂ membranes, using solar simulated light. An AM 1.5 filter was used to obtain one sun intensity, which was illuminated on the photoanode at an intensity of 100 mW/cm². A thermopile detector from Newport-Oriel was used for the measurements. A computer-controlled potentiostat (SI 1286, England) was used to control the potential and record the generated photocurrent. A 300 W solar simulator (69911, Newport-Oriel Instruments, USA) was used as the light source. The active area of the device was 0.15 cm².

### Results and Discussion

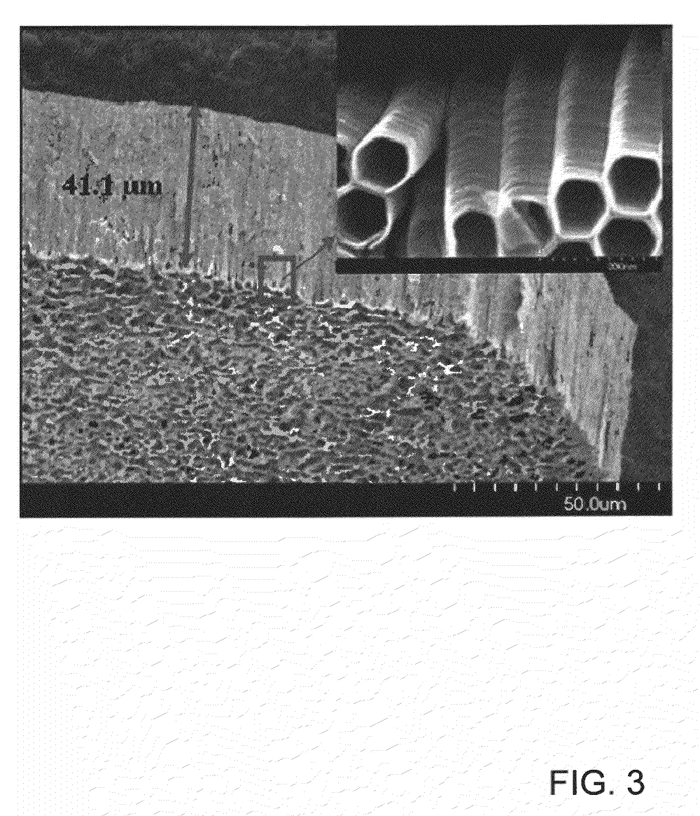

FIG. 3 shows an FESEM of the TiO₂ nanotube arrays formed by anodizing Ti in a solution of Na₂[H₂EDTA], NH₄F and ethylene glycol at 80 V for one hour. The cross-sectional view of the nanotubes reveals nanotubes 41.1 μm in length. The inset of FIG. 3 shows that the nanotubes were highly ordered, closely packed, and had a hexagonal pore structure (i.e., cross-sectional structure) towards the open end. The nanotubes were also hexagonal in shape along their length. The presence of hexagonal pores is a unique feature. While hexagonal arrangements of nanotubes have been observed, the pores of those nanotubes have not been hexagonal.

The process described herein to form the TiO₂ nanotubes in this example takes much less time to perform compared to other nanotube fabrication processes. The TiO₂ nanotube membrane detaches from the Ti substrate on its own when kept in air. Separation can be sped up by applying heat, such as from a hot air gun. This fabrication method is unique as no chemical agent is needed to remove the nanotube array from the Ti substrate, and no pre-treatment of the Ti substrate is required.

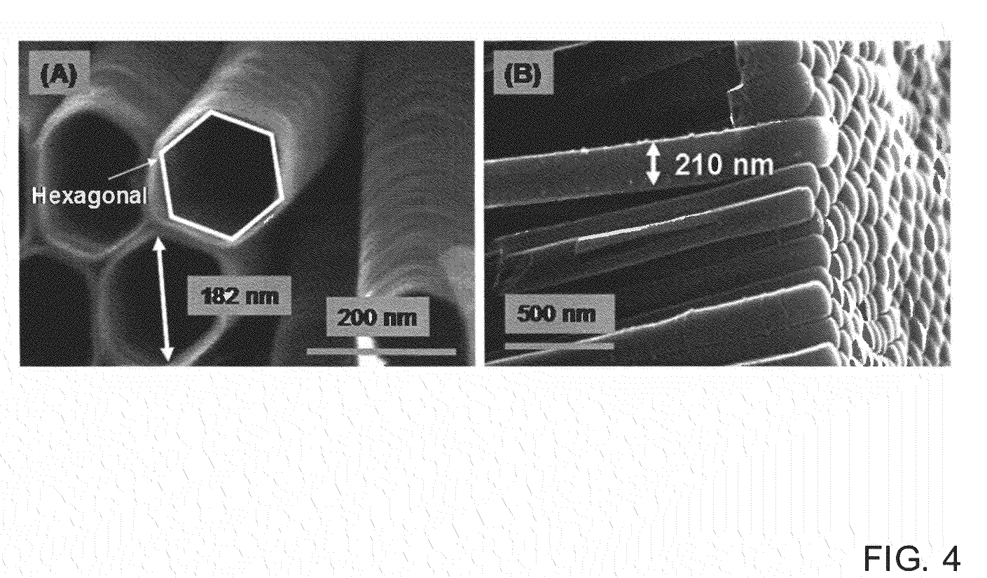

FIG. 4(A) is a FESEM image of the end portions of TiO₂ nanotubes formed by anodizing a titanium substrate for one hour. The FESEM image shows nanotubes that are hexagonal in nature with a pore diameter (i.e., the length of one of the diagonals of the hexagon formed by the interior walls of the nanotube) of 182 nm. FIG. 4(B) shows the closed end of the TiO₂ nanotubes. The external diameter of the TiO₂ tubes was 210 nm. Larger diameter nanotubes can be beneficial for photocatalytic and photovoltaic applications.

### Growth Rates of Thick TiO₂ Nanotubes Arrays and Membranes and the Role of EDTA

As the above discussion indicates, it appears that EDTA aids in forming TiO₂ nanotube arrays having a thickness 41.1 μm in just one hour. The current practice of growing ordered TiO₂ arrays involves anodizing a titanium substrate in a solution of NH₄F and ethylene glycol. In this example, the electrolytic solution also comprises an extra component, EDTA, an efficient chelating agent. In conventional electrolyte solutions, only fluoride attacks the surface of the titanium substrate, however, in the processes described herein, fluoride ions, F and [H₂EDTA]²⁻ both attack the Ti surface and speed up nanotube formation. The formation of nanotubes progresses through the three steps described below:

### Formation of the Passive Layer

In an aqueous acidic medium under applied potential, Ti oxidizes to form a thin layer of TiO₂ on Ti metal at the solid-liquid interface by Equation 1.

Ti+2H₂O→TiO_{2(anodic)}+3H_{2(cathodic)}↑ (1)

### Breakage of the Passive Layer

Although TiO₂ is stable thermodynamically in a pH range of 2-12, the presence of a complexing ligand (e.g., fluoride ion, F and [H₂EDTA]²⁻) and applied potential leads to substantial dissolution by Equations (2)-(4). F and [H₂EDTA]²⁻ compete between themselves to form complexes with Ti(IV):

TiO₂+6F⁻+4H⁺→[TiF₆]²⁻+2H₂O (2)

TiO₂+[H₂EDTA]²⁻+3H⁺→[TiO(HEDTA)]⁻+2H₂O (3)

TiO₂+[H₂EDTA]²⁻+2H⁺→[Ti(EDTA)]+2H₂O (4)

### Release of Fluoride Ion and Increase in pH:

Being a stronger chelating ligand, EDTA displaces F from [TiF₆]²⁻ according to Equation (5) or (6):

[TiF₆]²⁻+Na₂[H₂EDTA]→[Ti(EDTA)]12 NaF (5)

[TiF₆]²⁻+Na₂[H₂EDTA]→[TiO(HEDTA)]⁻+12 NaF (6)

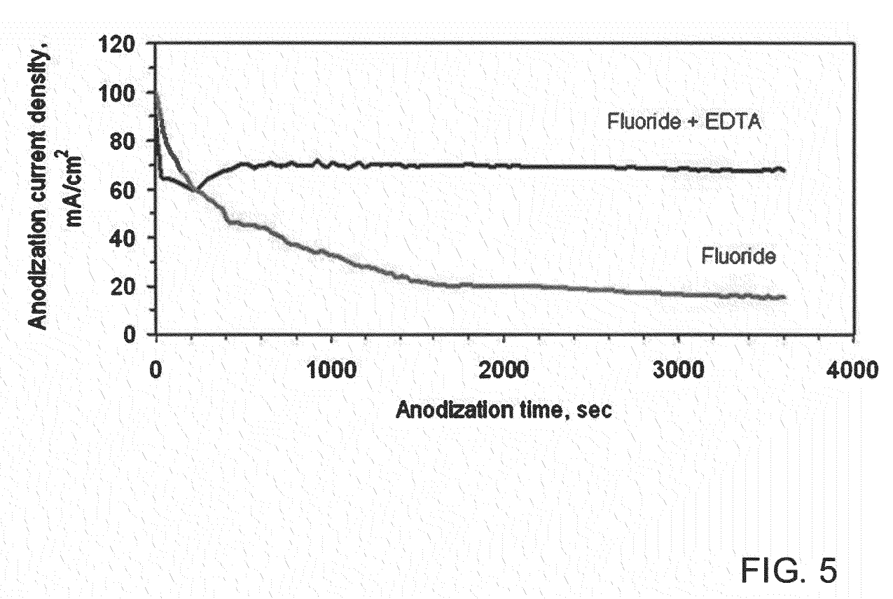

Equations (5) and (6) are written based on the evidence of FIG. 5.

FIG. 5 shows a plot of anodization current density versus time for the anodization of TiO₂ in fluoride+EDTA and fluoride-only solutions. It is seen from the curves that the current in the anodization curve is decreased when a fluoride-only solution is used. The anodization curve corresponding to the use of a fluoride+EDTA solution remains constant over time and does not decrease after one hour. This may be due to the release of free F in the (EDTA+F) solution. This leads to the extremely fast kinetics when (EDTA+F⁻) solution is used for anodization. This may be due to the release of free F in the (EDTA+F⁻) solution. This leads to fast kinetics when an EDTA+F⁻ solution is used for anodization.

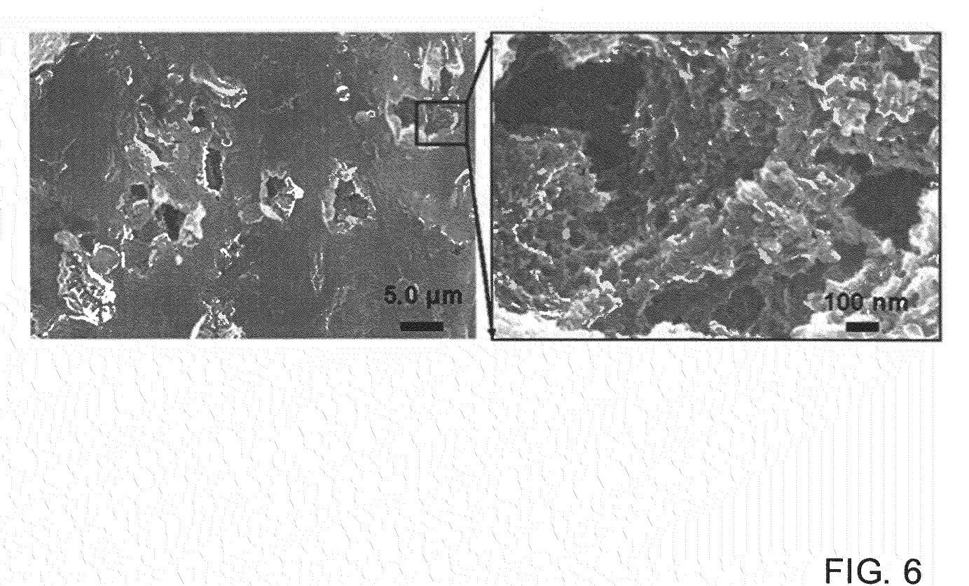

FIG. 6 is an SEM image of anodized Ti at 100 V in ethylene glycol+water (5 v %), +0.25 M Na₂[H₂EDTA] at 80 V for one hour. It is seen that no tube formation has taken place without the presence of F. Thus, F may be important for nanotube formation. This complex formation leads to breakage in the passive oxide layer, with disordered pit formation followed by the formation of ordered nanoporous structures. This nanoporous structure after further dissolution and cation-cation repulsion forms self-standing individual nanotubes on the Ti foil.

### Scaling of TiO₂ Membrane Area and the Formation TiO₂ Membranes

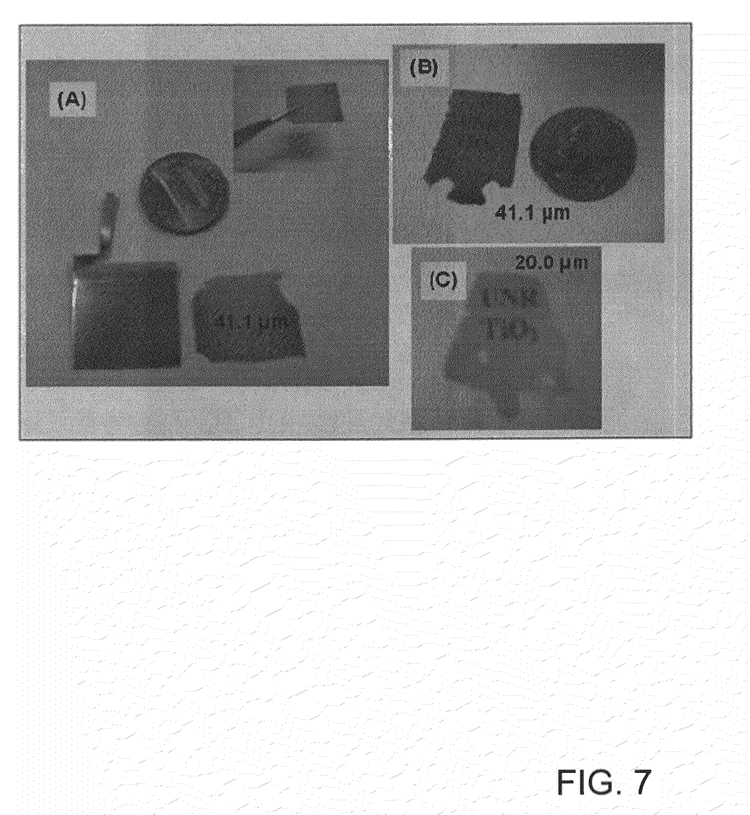

FIGS. 7(a) and 7(b) show the scaling of TiO₂ nanotube membrane area from 4 cm² to 16.5 cm², respectively. FIG. 7(b) also shows the transparency of the TiO₂ membranes. FIG. 7(c) shows a TiO₂ film made using a 30 minute anodization while keeping the other anodizing conditions the same. The 30 minute anodized membrane has an observed thickness of 20 μm, and is more transparent than the membrane anodized for one hour, which has an observed thickness of 41.1 μm. The processing techniques described herein result in free-standing TiO₂ nanotube membranes, which are transparent and can be handled easily with tweezers, as seen in the FIG. 7(a) inset. The TiO₂ nanotube membranes were obtained by etching the back-side barrier layer with aqueous HF.

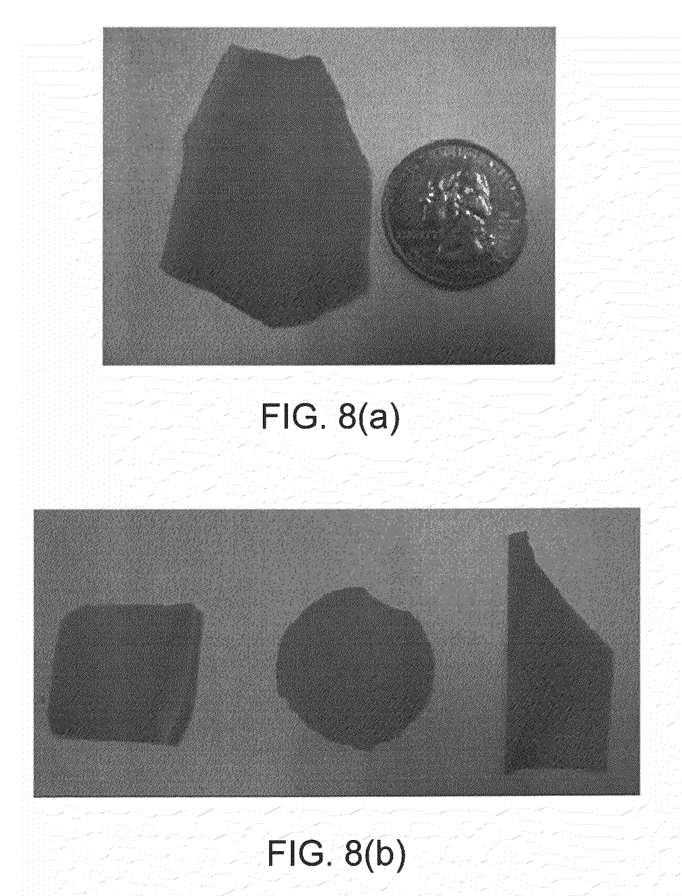

FIGS. 8(a) and 8(b) show that the processes described herein can produce TiO₂ arrays and membranes of arbitrary size and shape. Depending upon the size and shape of the underlying Ti foil or substrate, the shape of the TiO₂ array or membrane formed from the substrate can vary.

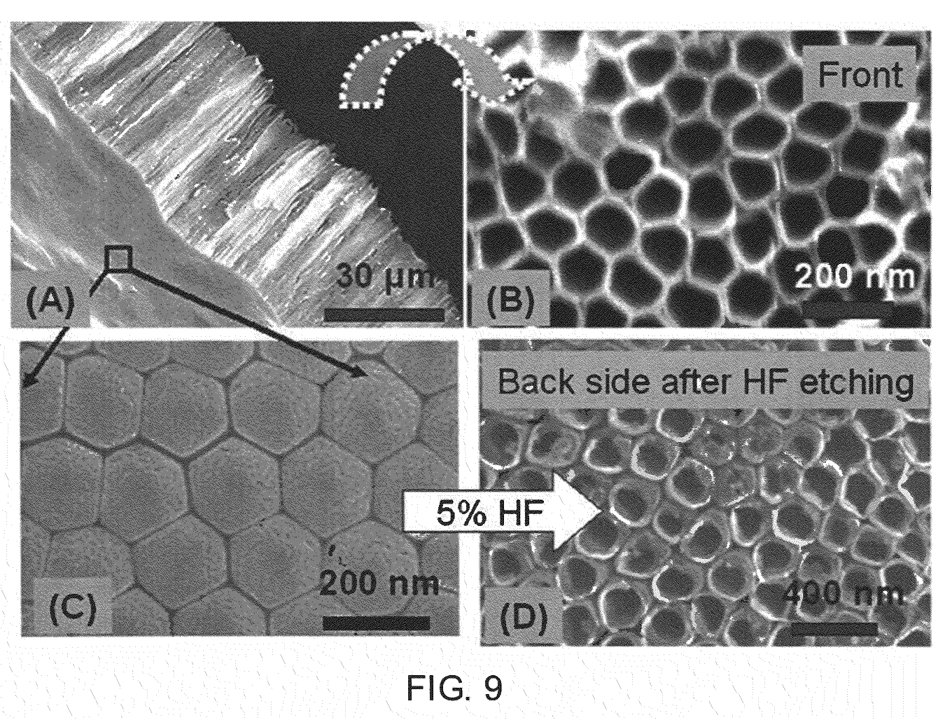

FIGS. 9(a)-9(d) show the ends of TiO₂ nanotubes in a TiO₂ nanotube membrane from front and back sides of the membrane. The front side of a TiO₂ membrane corresponds to the side that was distal to the titanium substrate when the TiO₂ membrane was attached to the substrate. The back side corresponds to the membrane side proximal to the titanium surface when the TiO₂ membrane was attached to the substrate. FIG. 9(a) shows a cross-sectional SEM image of a TiO₂ nanotube membrane detached from a Ti foil substrate after drying. FIGS. 9(b)-9(d) show close-up views of the front and back sides of TiO₂ nanotubes membranes. FIG. 9(d) shows the opened ends, or pores, of TiO₂ nanotubes after etching away the barrier layer with aqueous HF.

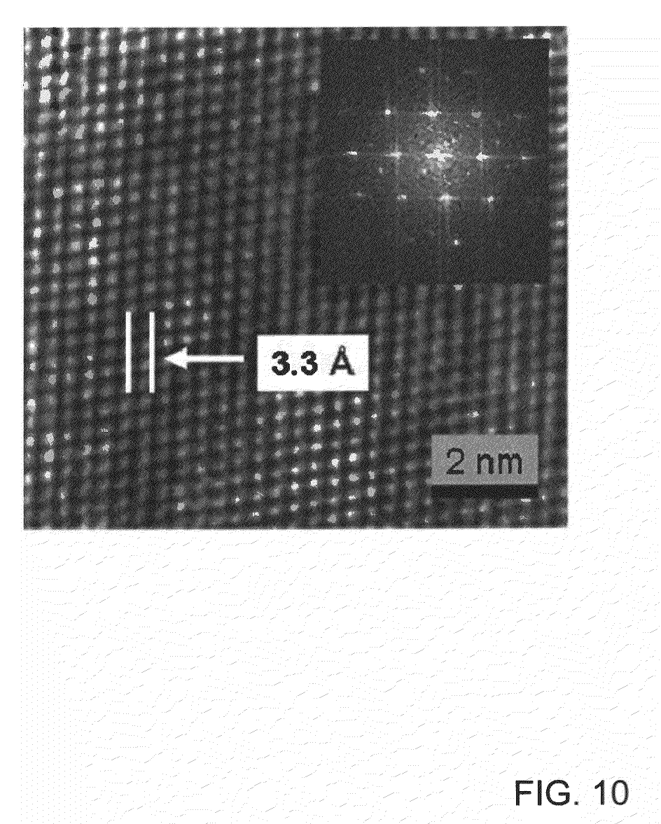

FIG. 10 is a high resolution transmission electron microscopy image and a fast Fourier transformation pattern of a TiO₂ nanotube membrane. The HRTEM image and FFT patterns of TiO₂ membrane shows that the nanotubes are highly crystalline anatase nanotubes.

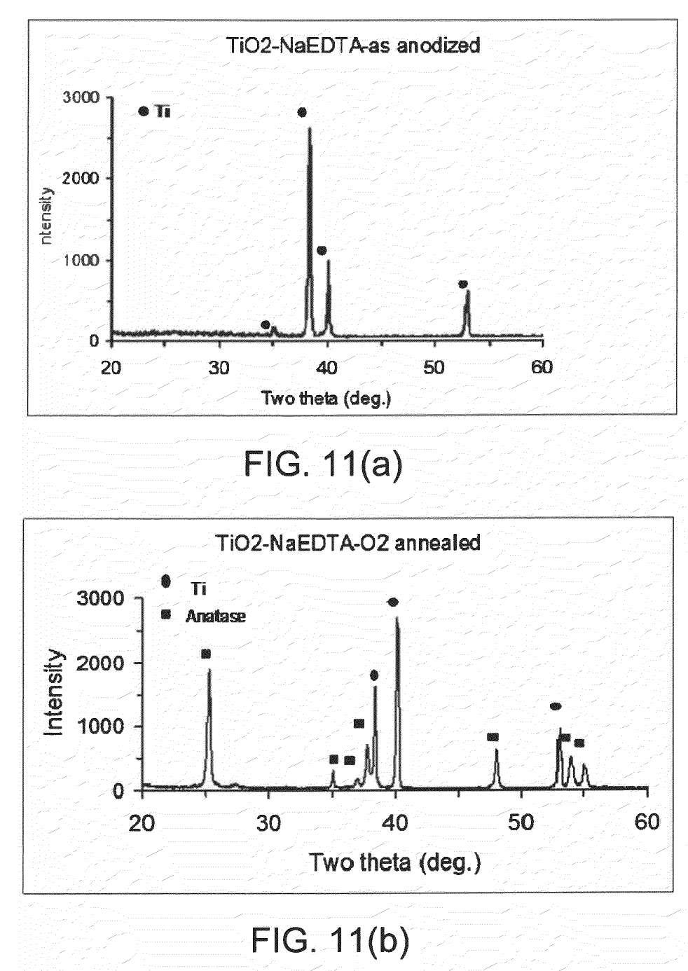

FIGS. 11(a) and (b), which show glancing angle X-ray diffraction plots of as-anodized and O₂ annealed TiO₂ nanotube membranes, respectively, support this conclusion. The diffraction plots of the as-prepared nanotube membrane showed Ti base peaks only, indicating that the nanotubes were amorphous in nature. The diffraction plot of the O₂ annealed membrane showed that the nanotubes were crystallized to the anatase phase.

### DRUV-Vis Studies

To examine the properties of photovoltaic devices comprising TiO₂ nanotube membranes, a TiO₂ membrane was attached on an FTO glass with Ti(OPrⁱ) and annealed in O₂ for 6 h in a CVD furnace. The annealed membrane on FTO glass was soaked in dye N719 for 16 h, washed in acetonitrile, dried and used for characterization and photovoltaic studies and comprises the dye-sensitized TiO₂ nanotube membrane sample. For comparison, a sample with the back side titanium substrate intact (the TiO₂ nanotube/titanium substrate sample) was also annealed in O₂ for 6 h and soaked in dye and made ready for characterization and photovoltaic tests.

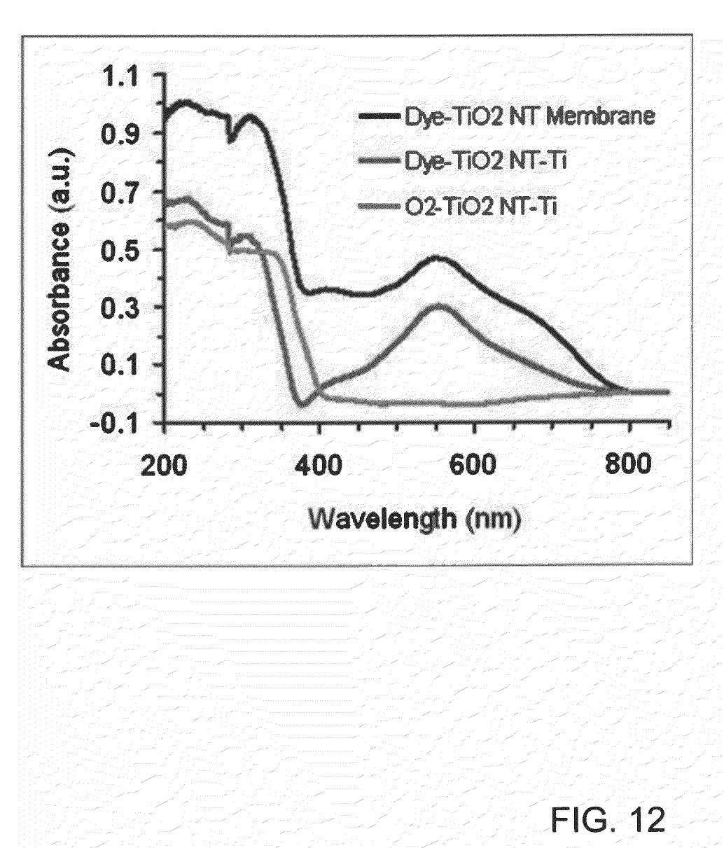

FIG. 12 shows diffuse reflectance ultraviolet and visible (DRUV-Vis) spectra of non-dye-sensitized TiO₂ nanotubes (O2— TiO₂ NT-Ti), dye-sensitized TiO₂ nanotube/titanium substrate structures (Dye-TiO₂ NT-Ti), and dye-sensitized TiO₂ membranes (Dye-TiO₂ NT Membrane). The absorbance of a system is an indirect measure of cell performance. The more the absorbance of the dye, the better the cell performance. FIG. 12 shows that the absorbance of the dye-sensitized detached TiO₂ membrane is better than the dye-sensitized TiO₂ nanotube/titanium substrate structure. This suggests that the Ti substrate is a hindrance in absorption of dye. Thus, removal of the titanium nanotube array from the titanium can improve photovoltaic performance.

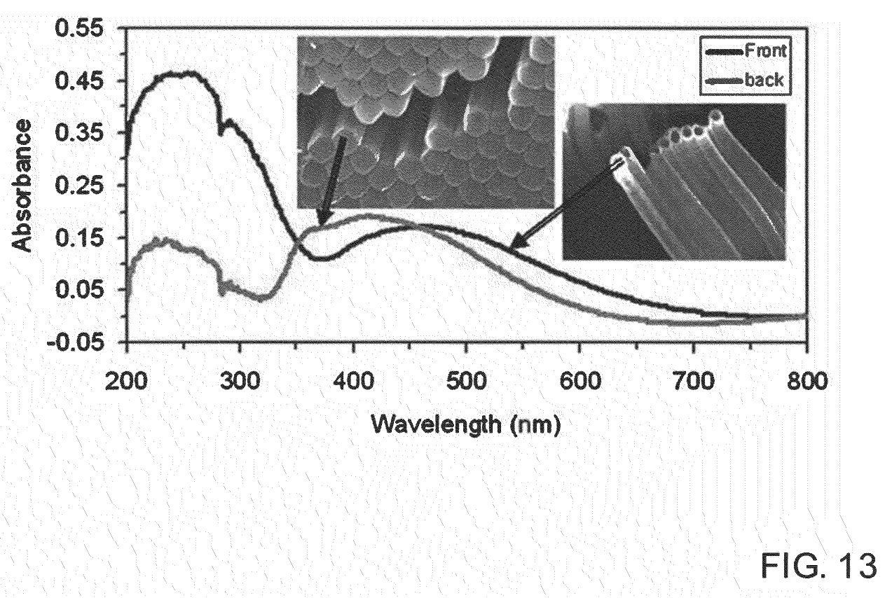

FIG. 13 shows the DRUV-Vis spectra of the frontside open ends and back side closed ends of TiO₂ nanotubes. Again, the front side of a TiO₂ nanotube corresponds to the nanotube end furthest from the titanium substrate while the nanotube is attached to the titanium substrate from which it is formed, and the back side of the TiO₂ nanotube corresponds to the nanotube end attached to the substrate during nanotube formation. FIG. 13 indicates that the absorbance of front side open ends is greater than that of the back side closed ends, which comprise a barrier layer that reflects more light. Thus, removing the barrier layer, which scatters light, can increase the absorbance of TiO₂ nanotubes.

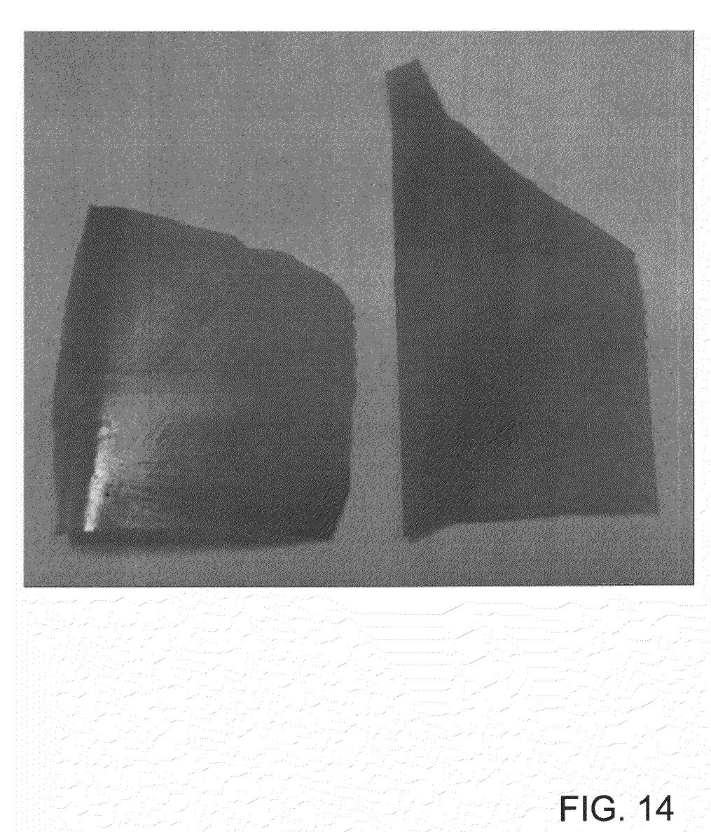

FIG. 14 is an image of TiO₂ nanotube membranes with the back side closed ends of the nanotubes facing either upwards (the membrane on the left) or downwards (the membrane on the right). The images show that a closed end side of a nanotube membrane is more reflective that an open ended side.

These measurements indicate that the performance of a dye-sensitive solar cell should increase when the TiO₂ barrier layer is etched and a TiO₂ nanotube membrane is used (instead of a TiO₂ nanotube membrane/titanium substrate structure).

### Photovoltaic Studies

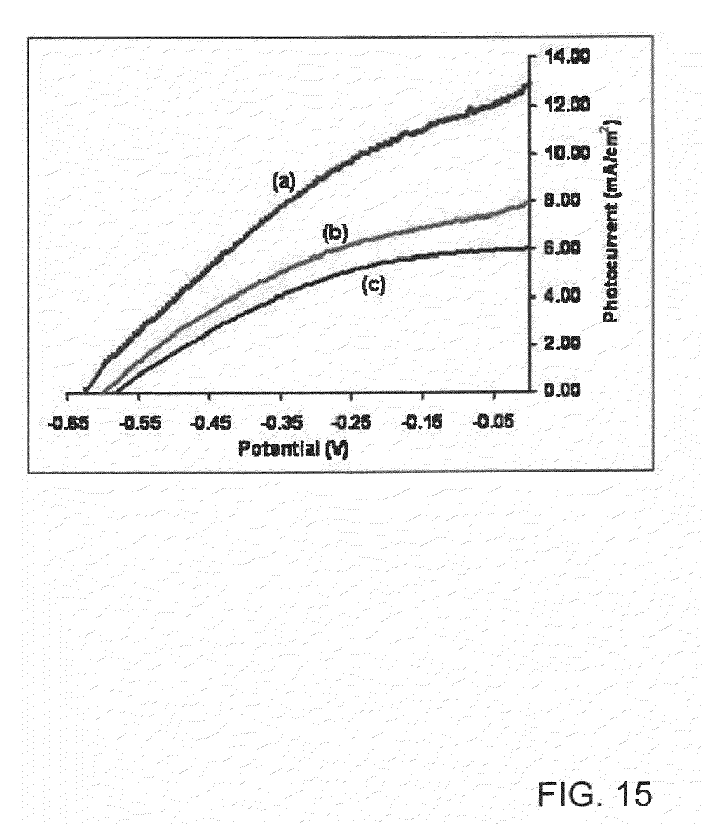

FIG. 15 and Table 1 show comparisons of photovoltaic properties of various DSSCs comprising TiO₂ nanotubes. FIG. 15 shows the circuit photocurrent vs. voltage plot of: (a) front-side illuminated TiO₂ membranes treated with Ti(OPrⁱ) and not having a barrier layer; (b) front-side illuminated TiO₂ nanotube array/titanium substrates structures treated with Ti(OPrⁱ), and (c) back-illuminated dye-sensitized TiO₂ nanostructure arrays/titanium substrates having no barrier layer. All titanium nanotubes were formed by anodization of a titanium substrate at 80 V and all DSSCS were illuminated at an intensity of AM 1.5, 100 mW cm⁻².

FIG. 15 shows that the front side illumination of the DSSC comprising the TiO₂ membrane with the barrier layer etched away yields a 12.9 mA/cm² short-circuit current (curve (a)), which is greater than the 7.9 mA/cm² short-circuit corresponding to the DSSC comprising the TiO₂ nanotubes/titanium substrate structure having the barrier layer (curve (b)). FIG. 15 also shows that the addition of Ti(OPrⁱ) increases the photoactivity. The addition of the Ti(OPrⁱ) treatment increases the short-circuit current from about 6 mA/cm² (curve (c)) to 8 mA/cm² (curve (b)). Thus, the removal of the barrier layer is associated with a greater increase in photocurrent (5 mA/cm²) relative to the increase in photocurrent associated with the addition of Ti(OPrⁱ) (2 mA/cm²). The increase in photocurrent due to the removal of barrier layer is likely due to the removal of a layer that reflects light and hinders absorbance, as described above in regards to the DRUV-Vis measurements.

There is also another likely factor behind the increase in the photocurrent due to the removal of the barrier layer. The photosensitive dye cannot flow through the TiO₂ nanotubes when there is a barrier layer. Thus, the wettability of the nanotubes is decreased when there is a barrier layer, as discussed above in regard to FIG. 1. This can be due to a reduction in the rate of charge recombination between photoinjected electrons in the substrate and the oxidized dye. Due to the presence of the more stoichiometric Ti in the barrier layer, the recombination rate of photogenerated charge pairs is increased. Removing the barrier layer creates a smooth transport of charge carriers from the TiO₂ nanotubes to the attached FTO glass, thus generating higher current densities. This new DSSC design comprising TiO₂ nanotube membranes with a removed barrier layer gives better photovoltaic properties (2.71% solar-to-electricity efficiency) than back side illuminated DSSCs comprising TiO₂ nanotube arrays attached to a titanium substrate (1.77% efficiency). The solar-to-electricity efficiency of the DSSC devices, the percentage of incident solar power converted to electrical power (watt/watt), described herein can be further improved by using different dyes such as porphyrin based dyes, and electrolytes.

DSSCs can be made with TiO₂ nanotubes longer than the 41 μm described in the above example. The TiO₂ nanotube membrane provides a three dimensional scaffold to contain the photosensitive dye. Thus, the longer the TiO₂ nanotubes, the thicker the layer of photosensitive dye in the DSSC, and the greater the capacity of photons striking the DSSC to cause photoexcitation of electrons in the photosensitive dye. The increased photoexcitation rate is due not only to the increased thickness of the photosensitive dye layer but also to the presence of the TiO₂ nanotubes. Incident photons striking the DSSC and passing through the photosensitive dye layer can be scattered by the TiO₂ nanotubes, thereby increasing the chance that the photon strikes a dye molecule.

Having both ends of the nanotubes open can improve the utility of the nanotubes. For example, performance can be improved in photovoltaic systems. Performance can also be improved in flow-through and filtration processes such as air purifiers, water purifiers, gas phase reactions NOx traps in vehicles and fuel cells.

TABLE 1
Photovoltaic device performance parameters of dye-sensitive solar cells
comprising different TiO₂ nanotube systems. Pt/FTO was used
as counter electrode. The measurements were done under AM 1.5
sunlight illumination (100 mW/cm²). The active area of the solar cells
was 0.15 cm². The fill factor is the ratio of the maximum power point
of the solar cell divided by the open circuit potential and the short
circuit current.

| | Short circuit | Open circuit | Fill | |
|---|---|---|---|---|
| | current | potential | factor | Efficiency |
| System | (mA/cm²) | (mV) | (%) | (%) |
| Dye-sensitized TiO₂ | 6.01 | 584 | 41 | 1.43 |
| nanotube array/Ti | | | | |
| substrate | | | | |
| Dye-sensitized TiO₂ | 7.9 | 599 | 38 | 1.77 |
| nanotube array/Ti | | | | |
| substrate treated with | | | | |
| Ti(OPrⁱ) | | | | |
| Dye-sensitized TiO₂ | 12.9 | 625 | 34 | 2.71 |
| membrane treated with | | | | |
| Ti(OPrⁱ) | | | | |

### CONCLUSIONS

Transparent, crack free TiO₂ membranes, 20-41 μm thick containing highly ordered hexagonal TiO₂ nanotubes have been synthesized. The maximum geometrical area obtained was 16.5 cm² with pore openings of 182 nm. The process of making TiO₂ nanotube membranes is green and very quick as 40 μm membranes can be formed in about one hour. The TiO₂ membranes have been subjected to photovoltaic tests. This new design to use TiO₂ nanotube membranes gives better photovoltaic properties (2.71% efficiency) than back-side illuminated DSSCs comprising TiO₂ nanotube arrays attached to titanium substrates (1.77% efficiency). The scattering of light by TiO₂ barrier layers at the back side of TiO₂ nanotube membranes and the reduced wettability of the TiO₂ nanotubes in the presence of the barrier layer decreases the performance of photovoltaic systems. It is also observed that DSSC photocurrent increases when Ti(OPrⁱ) is introduced in the system. This can be attributed to a reduction in the rate of charge recombination.

The TiO₂ nanotubes can be fabricated to comprise nanoparticles of various titanium compounds such as TiO₂ and TiSi₂ inside the TiO₂ nanotubes.

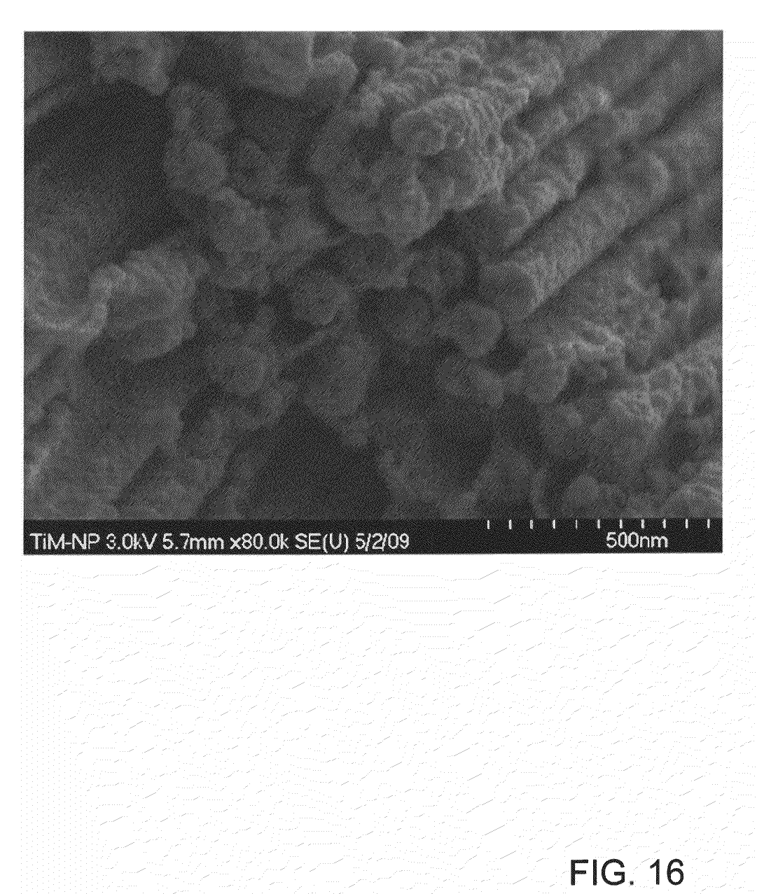

FIG. 16 shows an SEM image of TiO₂ nanotubes comprising TiO₂ nanoparticles inside the nanotubes. The TiO₂ nanoparticle/TiO₂ nanotube structure can be prepared by immersing a TiO₂ nanotube membrane into a TiCl₄ solution. The addition of TiO₂ nanoparticles into the TiO₂ nanotubes increases the structural integrity of the TiO₂ nanotubes, which can be used to make flexible, or bendable, solar cells. Conductive polymers such as polyaniline can be added to create flexible TiO₂ nanotubes.

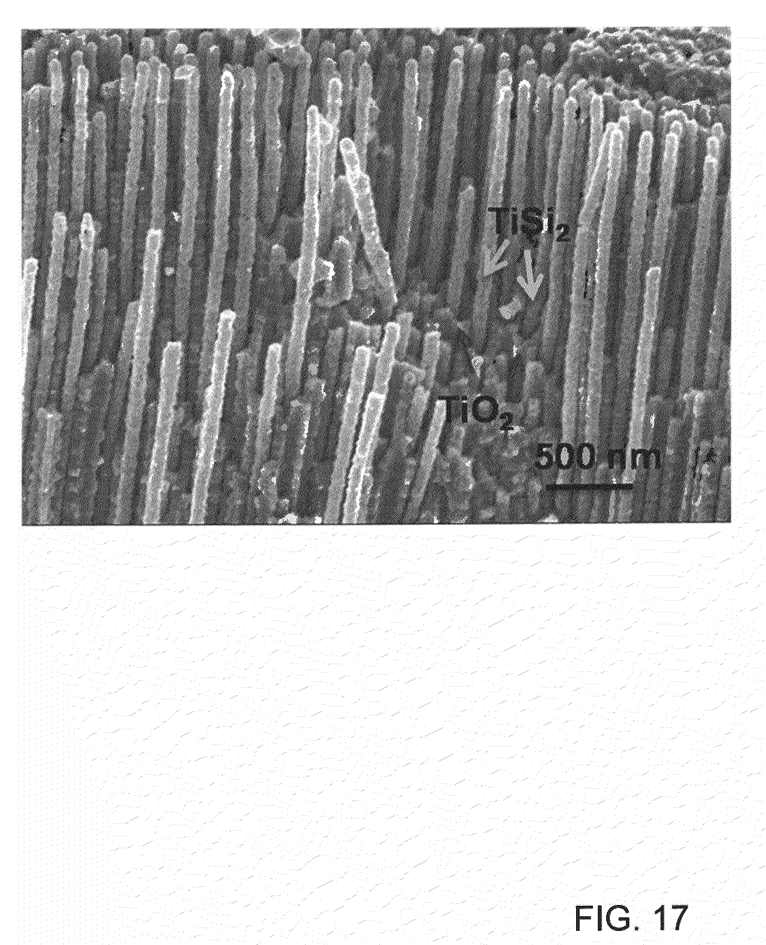

FIG. 17 shows an SEM image of TiO₂ nanotubes comprising TiSi₂ nanowires or nanorods inside the TiO₂ nanotubes. To prepare TiSi₂ nanowires/nanorods inside the large TiO₂ nanotubes, as-purchased large TiSi₂ particles are converted to nanoparticles by multi-step ball milling followed by ultrasonication in methanol. The ball-milled and ultrasonicated TiSi₂ particles are impregnated into the TiO₂ NT surface by the help of 1-octanol. The impregnated material is then annealed under nitrogen (N₂) atmosphere in a chemical vapor deposition furnace (CVD, FirstNano) at 500° C. for 6 h to crystallize the TiO₂ nanotube arrays as well as to remove organic materials. The prepared TiSi₂—TiO₂ material is then coated on Ti foil using a TiCl₄ solution followed by annealing at 500° C. for 3 h under N₂. This also helps the sintering of the TiSi₂ nanoparticles inside the TiO₂ nanotubes to form nanorod arrays. This process is found to be very simple to make a stable composite electrode of TiSi₂ and TiO₂ nanotube arrays (TiSi₂/TiO₂ nanotube). TiO₂ nanotubes comprising TiO₂ nanoparticles or TiSi₂ nanowires or nanorods can be used, for example, in catalysis, photoelectrochemical water splitting, air purification and water purification applications.

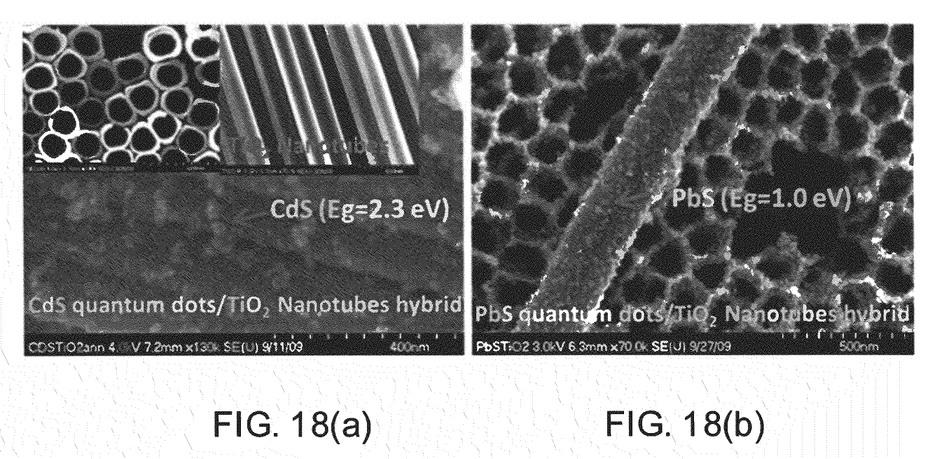

TiO₂ nanotube membranes can also be used to prepare low band gap quantum dots of compound semiconductors. FIGS. 18(a) and (b) are SEM images of CdS quantum dot (Eg=2.2 eV)/TiO₂ nanotube and PbS quantum dot (Eg=1.0 eV)/TiO₂ nanotube hybrid materials, respectively. To form CdS quantum dots on TiO₂ films, a solution of cadmium acetate dihydrate (2.35 g, 8.82 mmol), thiourea (0.95 g, 12.48 mmol), and 1-thioglycerol (0.95 mL, 10.95 mmol) in 200 mL of dimethylformamide was refluxed for 2 minutes under an argon atmosphere. Then, the CdS/TiO₂ films were sintered at 200° C. for 30 min under argon gas conditions. Due to the open ends on both the sides of the TiO₂ nanotubes and the large nanotube openings, these quantum dots form a uniform coating over the TiO₂ nanotubes. In a similar process PbS quantum dot/TiO₂ nanotube hybrid materials can be prepared. Quantum dot—nanotube hybrid materials can be used, for example, in photovoltaic and photocatalysis applications.

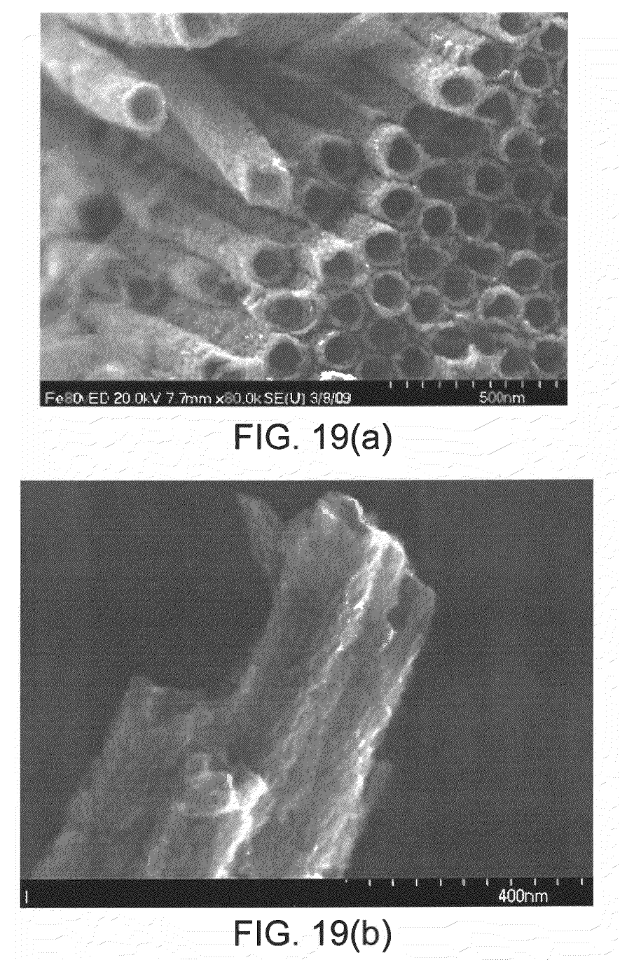

Disodium salt of ethylene diaminetetraacetic acid (Na₂[H₂EDTA]) as a complexing agent can also be used to prepare iron oxide (Fe₂O₃) nanotube arrays, as shown in FIGS. 19(a) and (b). Iron oxide nanotubes can be formed using processes similar to those described herein to form TiO₂ nanotubes.

Having illustrated and described the principles of the illustrated embodiments, the embodiments can be modified in various arrangements while remaining faithful to the concepts described above. In view of the many possible embodiments to which the principles of the disclosed invention may be applied, it should be recognized that the illustrated embodiments are only preferred examples and should not be taken as limiting the scope of the invention. Rather, the scope of the invention is defined by the following claims. We therefore claim as our invention all that comes within the scope and spirit of these claims.

We claim:

1. A method of forming a nanostructure membrane, the method comprising:
placing a substrate comprising titanium in an electrolyte bath, the electrolyte bath comprising:
water;
a fluoride compound;
a complexing agent; and
a polar organic solvent;
anodizing the substrate to form an array of titanium dioxide nanotubes on the substrate; and
allowing the array of titanium dioxide nanotubes to stand or applying heat to the array of titanium dioxide nanotubes until the array of titanium dioxide nanotubes separates from the substrate to create the nanostructure membrane, wherein the nanostructure membrane comprises the array of titanium dioxide nanotubes separated from the substrate.

2. The method of claim 1, wherein the polar organic solvent comprises an alkylene glycol.

3. The method of claim 2, wherein the alkylene glycol comprises ethylene glycol.

4. The method of claim 1, wherein the complexing agent comprises a polyamino carboxylic acid.

5. The method of claim 1, wherein the complexing agent comprises Na₂[H₂EDTA].

6. The method of claim 1, wherein the fluoride compound is hydrogen fluoride, ammonium fluoride, or an alkali fluoride.

7. The method of claim 1, wherein the polar organic solvent comprises ethylene glycol, the complexing agent comprises Na₂[H₂EDTA], and the fluoride compound comprises ammonium fluoride.

8. The method of claim 1, further comprising ultrasonicating the substrate during anodization.

9. The method of claim 1, wherein anodization is carried out using a platinum cathode.

10. The method of claim 1, wherein anodization is carried out at a potential of about 80 V.

11. The method of claim 1, wherein the nanostructure membrane has a side formerly attached to the substrate, the method further comprising opening ends of the array of titanium dioxide nanotubes of the nanostructure membrane on the side formerly attached to the substrate.

12. The method of claim 11, wherein the opening comprises contacting the side of the nanostructure membrane formerly attached to the substrate with an etchant.

13. The method of claim 1, wherein the array of titanium dioxide nanotubes is formed at a rate of greater than about 40 μm/hr.

14. The method of claim 1, wherein at least one nanotube in the nanostructure membrane is substantially hexagonal along its length.

15. The method of claim 1, wherein at least one nanotube in the nanostructure membrane has a pore diameter of at least 180 nm.

16. A method, comprising:
placing a substrate comprising titanium in an electrolyte bath, the electrolyte bath comprising:
water;
a fluoride compound;
a complexing agent; and
a polar organic solvent;
anodizing the substrate to form an array of titanium dioxide nanotubes on the substrate;
allowing the array of titanium dioxide nanotubes to stand or applying heat to the array of titanium dioxide nanotubes until the array of titanium dioxide nanotubes separates from the substrate to create a nanostructure membrane, wherein the nanostructure membrane comprises the array of titanium dioxide nanotubes separated from the substrate; and
attaching the nanostructure membrane to a transparent substrate to form a photosensitive electrode.

17. A solar cell formed by the method of claim 16.

18. The method of claim 16, wherein the nanostructure membrane is attached to the transparent substrate using Ti(OPrⁱ).

19. The method of claim 16, wherein the nanostructure membrane is attached to the substrate using a titanium alkoxide.

20. The method of claim 16, wherein the transparent substrate comprises fluorine doped tin oxide (FTO) glass.

21. The method of claim 16, further comprising electrically connecting the photosensitive electrode to a counter electrode.

22. The method of claim 16, further comprising filling the nanotubes of the nanostructure membrane with photosensitive dye and placing electrolyte between the photosensitive electrode and the counter electrode to create a solar cell.

23. The method of claim 22, further comprising illuminating the solar cell.

24. The method of claim 23, wherein the counter electrode is illuminated.

25. The method of claim 23, wherein the solar cell has an efficiency of greater than about 2.7%.

26. The method of claim 16, wherein the counter electrode is transparent.

27. The method of claim 16, wherein the counter electrode comprises platinum on fluorine doped tin oxide (FTO) glass.

28. The method of claim 16, the method further comprising immersing the nanostructure membrane in a TiCl₄ solution to form TiO₂ nanoparticles in the nanotubes of the membrane.
